(19) United States
(12) Patent Application Publication
(10) Pub. No.: US 2026/0040935 A1
(43) Pub. Date: Feb. 5, 2026

(54) INTERCONNECTION STRUCTURE AND METHOD OF FORMING THE SAME

(71) Applicant: United Microelectronics Corp., Hsinchu (TW)

(72) Inventors: Shin-Hung Li, Nantou County (TW); Shan-Shi Huang, Hsinchu City (TW)

(73) Assignee: United Microelectronics Corp., Hsinchu (TW)

(21) Appl. No.: 18/812,931

(22) Filed: Aug. 22, 2024

(30) Foreign Application Priority Data
Aug. 5, 2024 (TW) 113129217

(51) Int. Cl. H01L 23/528; H01L 21/768; H01L 23/522; H01L 23/532; H01L 27/00

(52) U.S. Cl. CPC H01L 23/5283; H01L 21/76831; H01L 23/5226; H01L 23/5329; H01L 21/76807; H01L 21/76879; H10D 99/00

(57) ABSTRACT

Provided are an interconnection structure and a method of forming the same. The interconnection structure includes a substrate, including a lower voltage device region and a higher voltage device region; a first dielectric layer, located on the substrate in the lower voltage device region and the higher voltage device region; an under-layer interconnection structure, located in the first dielectric layer in the lower voltage device region and the higher voltage device region; a second dielectric layer, located on the first dielectric layer in the lower voltage device region and the higher voltage device region; a first via plug and a first metal layer, located in the second dielectric layer in the lower voltage device region; and a U-shaped high k (dielectric constant) layer and a second metal layer, located in the second dielectric layer in the higher voltage device region.

### CROSS-REFERENCE TO RELATED APPLICATION

This application claims the priority benefit of Taiwan application serial no. 113129217, filed on Aug. 5, 2024. The entirety of the above-mentioned patent application is hereby incorporated by reference herein and made a part of this specification.

### BACKGROUND

### Technical Field

The disclosure relates to a semiconductor structure and a manufacturing method thereof, and particularly relates to an interconnection structure and a method of forming the same.

### Description of Related Art

With the trend of multi-tasking and miniaturization of semiconductor structures, electronic devices with various voltage requirements are formed in increasingly smaller semiconductor structures.

If high-voltage/medium-voltage devices and integrated low-voltage devices are directly integrated and manufactured, the thickness of the dielectric layer in the back-end-of-line (BEOL) process is often unable to withstand the voltage requirements of high-voltage/medium-voltage devices, thereby causing problems such as time dependent dielectric breakdown (TDDB) to occur.

Therefore, it is necessary to form additional multi-layer interconnection structures such as metal layers/metal plugs/dielectric layers in the semiconductor structure where high-voltage/medium-voltage devices and low-voltage devices are integrated and manufactured to thicken the dielectric layer of the overall interconnection, so as to withstand the voltage required by high-voltage/medium-voltage devices and improve the degree of tolerance of TDDB.

However, such a method requires the addition of a multi-layer interconnection structure process of multiple metal layers/metal plugs/dielectric layers, which significantly increases the manufacturing cost and the manufacturing time.

### SUMMARY

The disclosure provides an interconnection structure and a method of forming the same. In a higher voltage device region, by surrounding a bottom surface and sidewalls of a metal layer with a U-shaped high k layer, it improves the time dependent dielectric breakdown (TDDB) thereof, and at the same time, reduces the need to form additional multi-layer interconnection structures such as metal layers/metal plugs/dielectric layers in order to withstand the voltage requirements of higher voltage devices, thereby reducing the manufacturing cost and the manufacturing time.

An embodiment of the disclosure provides an interconnection structure, including a substrate, including a lower voltage device region and a higher voltage device region; a first dielectric layer, located on the substrate in the lower voltage device region and the higher voltage device region; an under-layer interconnection structure, located in the first dielectric layer in the lower voltage device region and the higher voltage device region; a second dielectric layer, located on the first dielectric layer in the lower voltage device region and the higher voltage device region; a first via plug and a first metal layer, located in the second dielectric layer in the lower voltage device region; and a U-shaped high k layer and a second metal layer, located in the second dielectric layer in the higher voltage device region. The U-shaped high k layer surrounds a bottom surface and sidewalls of the second metal layer, and a bottom surface of the U-shaped high k layer and a bottom surface of the first metal layer are at a same level in a stacking direction.

In some embodiments, the substrate including the lower voltage device region and the higher voltage device region is the substrate including a low-voltage device and a medium-voltage device, the substrate including a low-voltage device and a high-voltage device, or the substrate including a medium-voltage device and a high-voltage device.

In some embodiments, a voltage operating range of the low-voltage device is 5V or less, a voltage operating range of the medium-voltage device is 6V to 10V, and a voltage operating range of the high-voltage device is 20V or more.

In some embodiments, a dielectric constant of the U-shaped high k layer is greater than a dielectric constant of the second metal layer.

In some embodiments, the U-shaped high k layer has a dielectric constant of 7 to 10; and the U-shaped high k layer includes SiN, SiON, SiCN, or HfOx composite.

An embodiment of the disclosure provides a method of forming an interconnection structure, including the following steps. A substrate including a lower voltage device region and a higher voltage device region is provided. A first dielectric layer is formed on the substrate in the lower voltage device region and the higher voltage device region. An under-layer interconnection structure is formed in the first dielectric layer in the lower voltage device region and the higher voltage device region. A second dielectric layer is formed on the first dielectric layer in the lower voltage device region and the higher voltage device region. A first trench and a second trench are formed in the second dielectric layer, where the first trench is located in the lower voltage device region, and the second trench is located in the higher voltage device region. A U-shaped high k layer is formed on a bottom surface and sidewalls of the second trench. A bottom of the first trench is etched to form a first via exposing the under-layer interconnection structure. The first via, the first trench, and the second trench are filled with a conductive material to form a first via plug, a first metal layer, and a second metal layer respectively, where a bottom surface of the U-shaped high k layer and a bottom surface of the first metal layer are at a same level in a stacking direction.

In some embodiments, the substrate including the lower voltage device region and the higher voltage device region is the substrate including a low-voltage device and a medium-voltage device, the substrate including a low-voltage device and a high-voltage device, or the substrate including a medium-voltage device and a high-voltage device. A voltage operating range of the low-voltage device is 5V or less, a voltage operating range of the medium-voltage device is 6V to 10V, and a voltage operating range of the high-voltage device is 20V or more.

In some embodiments, a dielectric constant of the U-shaped high k layer is greater than a dielectric constant of the second metal layer.

In some embodiments, the U-shaped high k layer has a dielectric constant of 7 to 10; and the U-shaped high k layer includes SiN, SiON, SiCN, or HfOx composite.

In some embodiments, the step of forming the U-shaped high k layer on the bottom surface and the sidewalls of the second trench includes conformally forming a high k layer on the first trench and the second trench; removing the high k layer on the second trench; and after the conductive material is filled into the first via, the first trench, and the second trench, performing a comprehensive planarization step to remove the high k layer on the second dielectric layer so as to form the U-shaped high k layer.

An embodiment of the disclosure provides another interconnection structure, including a substrate, including a lower voltage device region and a higher voltage device region; a first dielectric layer, located on the substrate in the lower voltage device region and the higher voltage device region; an under-layer interconnection structure, located in the first dielectric layer in the lower voltage device region and the higher voltage device region; a second dielectric layer, located on the first dielectric layer in the lower voltage device region and the higher voltage device region; a first via plug and a first metal layer, located in the second dielectric layer in the lower voltage device region; and a U-shaped high k layer and a second metal layer, located in the second dielectric layer in the higher voltage device region. The U-shaped high k layer surrounds a bottom surface and sidewalls of the second metal layer, and a bottom surface of the U-shaped high k layer is higher than a bottom surface of the first metal layer in a stacking direction.

In some embodiments, the substrate including the lower voltage device region and the higher voltage device region is the substrate including a low-voltage device and a medium-voltage device, the substrate including a low-voltage device and a high-voltage device, or the substrate including a medium-voltage device and a high-voltage device.

In some embodiments, a voltage operating range of the low-voltage device is 5V or less, a voltage operating range of the medium-voltage device is 6V to 10V, and a voltage operating range of the high-voltage device is 20V or more.

In some embodiments, a dielectric constant of the U-shaped high k layer is greater than a dielectric constant of the second metal layer.

In some embodiments, the U-shaped high k layer has a dielectric constant of 7 to 10; and the U-shaped high k layer includes SiN, SiON, SiCN, or HfOx composite.

An embodiment of the disclosure provides another method of forming an interconnection structure, including the following steps. A substrate including a lower voltage device region and a higher voltage device region is provided. A first dielectric layer is formed on the substrate in the lower voltage device region and the higher voltage device region. An under-layer interconnection structure is formed in the first dielectric layer in the lower voltage device region and the higher voltage device region. A second dielectric layer is formed on the first dielectric layer in the lower voltage device region and the higher voltage device region. An elongated via is formed in the second dielectric layer in the lower voltage device region. The second dielectric layer around an upper half part of the elongated via is removed to form a first via and a first trench located above the first via. A second trench is formed in the second dielectric layer in the higher voltage device region. A U-shaped high k layer is formed on a bottom surface and sidewalls of the second trench. The first via, the first trench, and the second trench are filled with a conductive material to form a first via plug, a first metal layer, and a second metal layer respectively, where a bottom surface of the U-shaped high k layer is higher than a bottom surface of the second metal layer in a stacking direction.

In some embodiments, the substrate including the lower voltage device region and the higher voltage device region is the substrate including a low-voltage device and a medium-voltage device, the substrate including a low-voltage device and a high-voltage device, or the substrate including a medium-voltage device and a high-voltage device. A voltage operating range of the low-voltage device is 5V or less, a voltage operating range of the medium-voltage device is 6V to 10V, and a voltage operating range of the high-voltage device is 20V or more.

In some embodiments, a dielectric constant of the U-shaped high k layer is greater than a dielectric constant of the second metal layer.

In some embodiments, the U-shaped high k layer has a dielectric constant of 7 to 10; and the U-shaped high k layer includes SiN, SiON, SiCN, or HfOx composite.

In some embodiments, the step of forming the U-shaped high k layer on the bottom surface and the sidewalls of the second trench includes conformally forming a high k layer on the first trench, the first via, and the second trench; removing the high k layer on the second trench and the first via; after the conductive material is filled into the first via, the first trench, and the second trench, performing a comprehensive planarization step to remove the high k layer on the second dielectric layer so as to form the U-shaped high k layer.

Based on the above, in the higher voltage device region, by surrounding the bottom surface and the sidewalls of the metal layer with the U-shaped high k layer, it improves the time dependent dielectric breakdown (TDDB) thereof, and at the same time, reduces the need to form additional multi-layer interconnection structures such as metal layers/metal plugs/dielectric layers in order to withstand the voltage requirements of higher voltage devices, thereby reducing the manufacturing cost and the manufacturing time.

### BRIEF DESCRIPTION OF THE DRAWINGS

FIG. 1A to FIG. 1F are schematic cross-sectional views of a method of forming an interconnection structure according to a first embodiment of the disclosure.

FIG. 2A to FIG. 2G are schematic cross-sectional views of a method of forming an interconnection structure according to a second embodiment of the disclosure.

### DESCRIPTION OF THE EMBODIMENTS

The disclosure will be described more comprehensively below with reference to the drawings of the present embodiment. However, the disclosure may also be implemented in various forms, and shall not be limited to the embodiments described herein. For the sake of clarity, thicknesses of layers and regions in the drawings are enlarged. The same or similar reference numbers indicate the same or similar elements, and the following paragraphs will not repeat them one by one.

It will be understood that when an element is referred to as being “on” or “connected to” another element, it may be directly on or connected to the other element, or intervening elements may be present. If an element is referred to as being “directly on” or “directly connected to” another element, there are no intervening elements present. As used herein, “connection” may refer to both physical and/or electrical connections, and “electrical connection” or “coupling” may refer to the presence of other elements between two elements.

As used herein, “about”, “approximately”, or “substantially” includes the stated value and the average within an acceptable deviation of the particular value as determined by one of ordinary skill in the art, taking into account the measurement in question and the specific amount of measurement-related error (i.e., the limitations of the measurement system). For example, “about” may mean within one or a plurality of standard deviations of the stated value, or within ±30%, ±20%, ±10%, ±5%. Furthermore, as used herein, “about”, “approximately”, or “substantially” may encompass an acceptable range of deviation or standard deviation depending on optical properties, etching properties or other properties, and one standard deviation does not apply to all properties.

The wording used herein is used only to illustrate exemplary embodiments, but not to limit the disclosure. In this case, a singular form includes a plural form unless otherwise explained in the context.

The method of forming an interconnection structure mainly described in the disclosure includes various steps, such as deposition processes (e.g., physical vapor deposition (PVD), chemical vapor deposition (CVD), plasma enhanced chemical vapor deposition (PE-CVD), atomic layer deposition (ALD), sputtering, etc.), removal processes (e.g., wet etching, dry etching, chemical mechanical planarization (CMP), etc.), and/or patterning processes (e.g., lithography/etching), but the disclosure is not limited thereto.

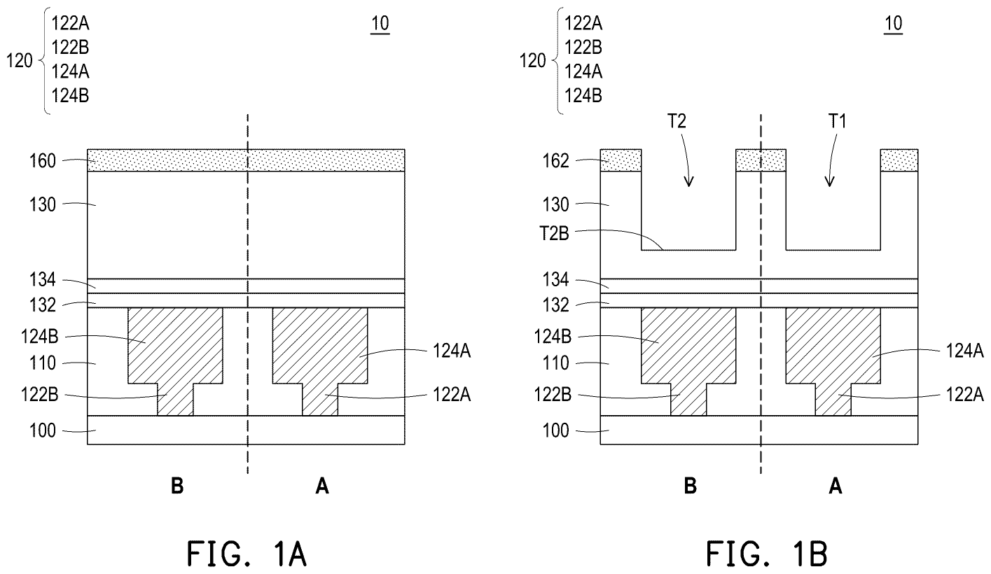

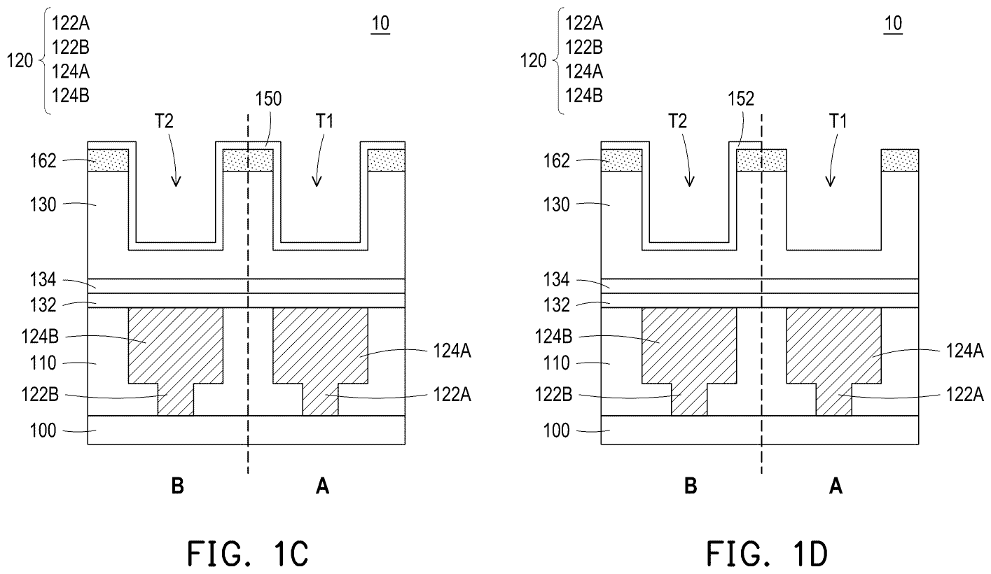

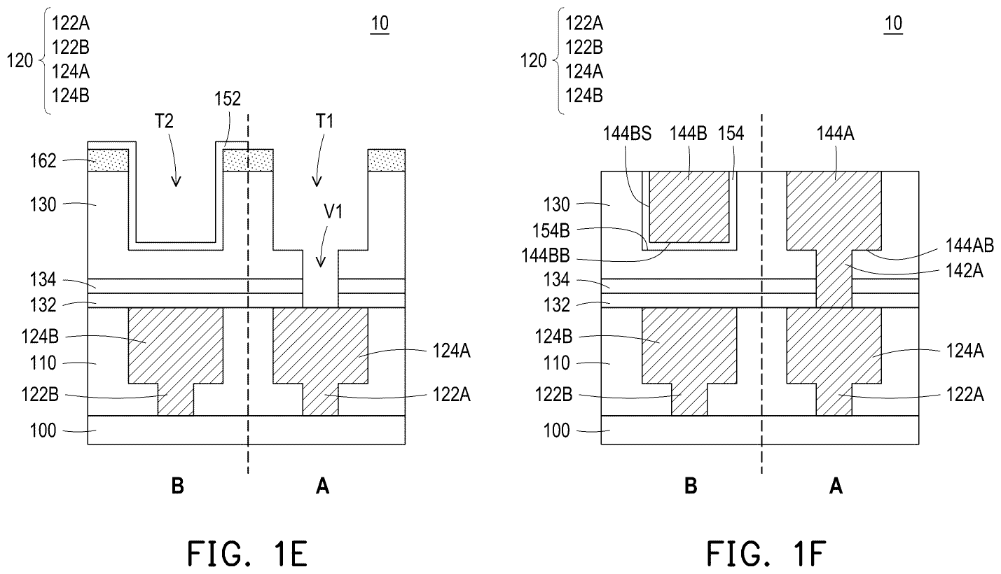

FIG. 1A to FIG. 1F are schematic cross-sectional views of a method of forming an interconnection structure according to a first embodiment of the disclosure.

First, referring to an interconnection structure 10 of FIG. 1A, a substrate 100 is provided. The substrate 100 may include a lower voltage device region A and a higher voltage device region B. For the convenience of illustration, the lower voltage device region A and the higher voltage device region B of FIG. 1A are located on adjacent sides. However, the actual application structure is not limited thereto. There may also be other components between the lower voltage device region A and the higher voltage device region B.

The substrate 100 may include various semiconductor structures formed by various semiconductor front-end-of-line (FEOL) processes.

Moreover, the lower voltage device region A and the higher voltage device region B are relative concepts. For example, the substrate 100 may include a low-voltage device and a medium-voltage device, or the substrate 100 may include a low-voltage device and a high-voltage device, or the substrate 100 may include a medium-voltage device and a high-voltage device.

A voltage operating range of the high-voltage device may be 20V or more, a voltage operating range of the medium-voltage device may be 6V to 10V, and a voltage operating range of the low-voltage device may be 5V or less.

Continuing to refer to FIG. 1A, a first dielectric layer 110 is formed on the substrate 100 in the lower voltage device region A and the higher voltage device region B, and an under-layer interconnection structure 120 is formed in the first dielectric layer 110 of the lower voltage device region A and the higher voltage device region B.

The first dielectric layer 110 may use various dielectric materials as required, such as nitride (e.g., silicon nitride, silicon oxynitride), carbide (e.g., silicon carbide), SiCN, oxide (e.g., silicon oxide), tetraethyl orthosilicate (TEOS), borosilicate glass (BSG), phosphoric silicate glass (PSG), borophosphosilicate glass (BPSG), low dielectric constant oxide (e.g., carbon doped oxide, SiCOH), or some other suitable dielectric materials.

The under-layer interconnection structure 120 may include a through-via plug 122A and a metal layer 124A in the lower voltage device region A, and a through-via plug 122B and a metal layer 124B in the higher voltage device region B. In FIG. 1A, in the lower voltage device region A and the higher voltage device region B, only one through-via plug 122A, metal layer 124A, through-via plug 122B, and metal layer 124B are shown respectively. However, the actual structure is not limited thereto, and may include a plurality of or one through-via plug 122A, metal layer 124A, through-via plug 122B, and metal layer 124B.

The above-mentioned through-via plug 122A, metal layer 124A, through-via plug 122B, and metal layer 124B may be formed of various conductive materials, such as tantalum, titanium, copper, tungsten, aluminum, or some other suitable conductive materials.

Continuing to refer to FIG. 1, next, a second dielectric layer 130 is formed on the first dielectric layer 110 in the lower voltage device region A and the higher voltage device region B.

Furthermore, one or more interlayer dielectric layers may be formed between the first dielectric layer 110 and the second dielectric layer 130 for the purpose of etching the upper layer or protecting the lower layer, such as a first interlayer dielectric layer 132 shown in FIG. 1A and a second interlayer dielectric layer 134, but the disclosure is not limited thereto.

The second dielectric layer 130, the first interlayer dielectric layer 132, and the second interlayer dielectric layer 134 are as described above for the first dielectric layer 110 and may use various dielectric materials as required, such as nitride (e.g., silicon nitride, silicon oxynitride), carbide (for example, silicon carbide), SiCN, oxide (e.g. silicon oxide), tetraethyl orthosilicate (TEOS), borosilicate glass (BSG), phosphoric silicate glass (PSG), borophosphosilicate glass (BPSG), low dielectric constant oxide (e.g., carbon doped oxide, SiCOH), or some other suitable dielectric materials. In other embodiments, the second interlayer dielectric layer 134 may include a material with a dielectric constant less than a dielectric constant of silicon oxide (e.g., about 3.9). In other embodiments, ultra low-k (ULK) dielectric materials having a dielectric constant less than about 2.6 may be included. For example, but not limited thereto, the first interlayer dielectric layer 132, the second interlayer dielectric layer 134, and the second dielectric layer 130 may be SiCN, TEOS, or ultra low-k materials in order. The ultra low-k material may be, for example, porous silicon dioxide material or the like.

Next, refer to FIG. 1A and FIG. 1B at the same time. As shown in FIG. 1B, in order to form a first trench T1 in the lower voltage device region A in the second dielectric layer 130 and a second trench T2 in the higher voltage device region B in the second dielectric layer 130, a hardmask layer 160 may be formed on the second dielectric layer 130 in the lower voltage device region A and the higher voltage device region B, as shown in FIG. 1A. The hardmask layer 160 is then patterned to form a hardmask 162 that defines the first trench T1 and the second trench T2, and then the first trench T1 and the second trench T2 are etched. This is one of the methods of forming the first trench T1 and the second trench T2, and the actual formation method is not limited thereto.

Refer to both FIG. 1B and FIG. 1F. Next, in the higher voltage device region B, a U-shaped high k layer 154 is formed on a bottom surface T2B and sidewalls T2S of the second trench T2.

During the formation of the U-shaped high k layer 154, a first via plug 142A and a first metal layer 144A in the lower voltage device region A will be formed at the same time, as shown in the formation method of FIG. 1C to FIG. 1F, but the disclosure is not limited thereto.

Refer first to FIG. 1C, a high k layer 150 is conformally deposited on the first trench T1, the second trench T2, and the second dielectric layer 130. If the hardmask 162 is used to define the first trench T1 and the second trench T2 as in the embodiment, then as shown in FIG. 1C, the high k layer 150 is conformally deposited on the first trench T1, the second trench T2, and the hardmask 162.

Next, as shown in FIG. 1D, the high k layer 150 on the first trench T1 in the lower voltage device region A is selectively removed to form a high k layer 152 that only exists on the second trench T2 in the higher voltage device region B.

Next, as shown in FIG. 1E, the second dielectric layer 130 at part of the bottom of the first trench T1 is etched. As shown in FIG. 1A to FIG. 1F, there are a first interlayer dielectric layer 132 and a second interlayer dielectric layer 134, and the two layers are etched simultaneously to form a first via V1 exposing the under-layer interconnection structure 120.

Then, the first via V1, the first trench T1, and the second trench T2 are filled with a conductive material, such as tantalum, titanium, copper, tungsten, aluminum, or some other suitable conductive materials, to electrically connect with the under-layer interconnection structure 120; for example, copper is filled into the first via V1, the first trench T1, and the second trench T2.

Then, a comprehensive planarization process is performed on the entire interconnection structure 10. For example, methods such as chemical mechanical polishing (CMP) are used to remove the excess conductive material, the high k layer 152, and the hardmask 162, so that the first via V1, the first trench T1, and the second trench T2 filled with the conductive material respectively form the first via plug 142A, the first metal layer 144A, and a second metal layer 144B, and the high k layer 152 is formed in the higher voltage device region B as the U-shaped high k layer 154 surrounding a bottom surface 144BB and sidewalls 144BS of the second metal layer 144B as shown in FIG. 1F.

As shown in FIG. 1F, the bottom surface 154B of the U-shaped high k layer 154 is at a same level as a bottom surface 144AB of the first metal layer 144A in a stacking direction.

A dielectric constant of the U-shaped high k layer 154 is higher than a dielectric constant of the second dielectric layer 130. For example, the U-shaped high k layer 154 has a dielectric constant of about 7 to 10, and the second dielectric layer 130 has a dielectric constant of about 3.1 to 3.9, but the disclosure is not limited to these values.

Moreover, the U-shaped high k layer 154 may include high k dielectric materials such as HfO₂, TiO₂, HfZrO, Ta₂O₃, HfSiO₄, ZrO₂, ZrSiO₂, LaO, AlO, ZrO, TiO, Ta₂O₅, Y₂O₃, BaZrO, HfLaO, HfSiO, LaSiO, AlSiO, HfTaO, HfTIO, Al₂O₃, SIN, SION, SiCN, or HfOx composite whose dielectric constant is greater than silicon oxide, with SiN, SiON, SiCN, or HfOx composite being preferred, and may be formed by methods such as atomic layer deposition (ALD) process or metal-organic chemical vapor deposition (MOCVD), but the disclosure is not limited thereto.

Since the U-shaped high k layer 154 located in the higher voltage device region B surrounds the bottom surface 144BB and the sidewalls 144BS of the second metal layer 144B, it may make the overall dielectric layer in the higher voltage device region B have higher voltage withstand capability and improve the time dependent dielectric breakdown (TDDB) thereof. Therefore, it is no longer necessary to use the processing method in the conventional technology where the additional multi-layer interconnection structures such as metal layers/metal plugs/dielectric layers are added in the higher voltage device A to increase the thickness of the dielectric layer so as to withstand a higher voltage; that is to say, the disclosure forms the U-shaped high k layer 154 in the higher voltage device region B to surround the bottom surface 144BB and the sidewalls 144BS of the second metal layer 144B, so as to improve the time dependent dielectric breakdown (TDDB) thereof, and at the same time, reduce the need to form additional multi-layer interconnection structures such as metal layers/metal plugs/dielectric layers in order to withstand the voltage requirements of higher voltage devices, thereby reducing the manufacturing cost and the manufacturing time.

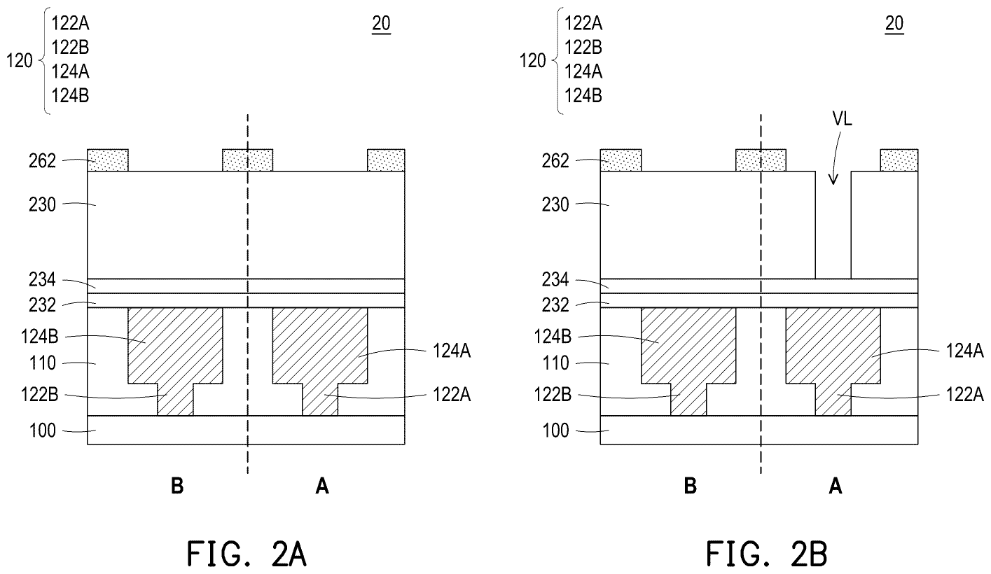

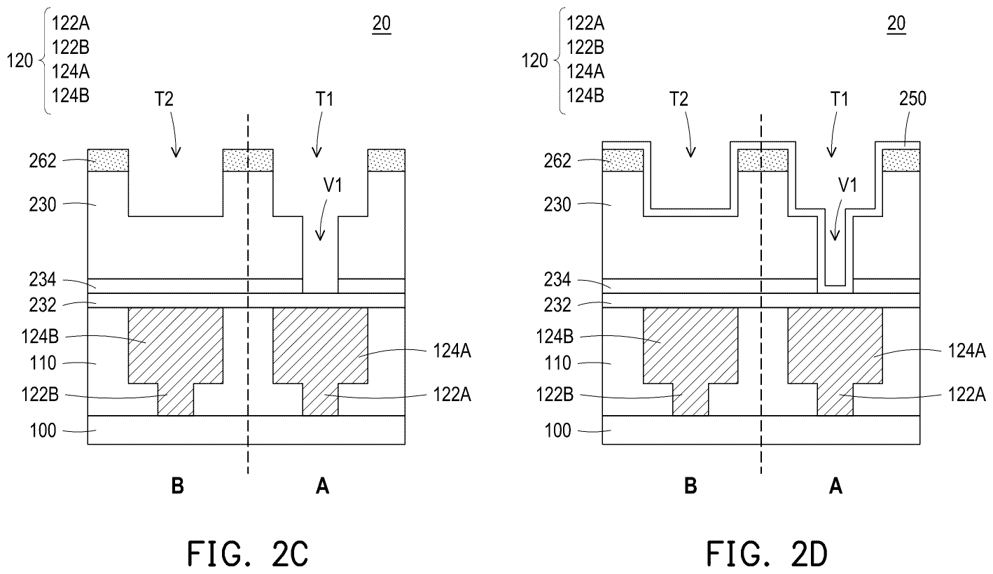

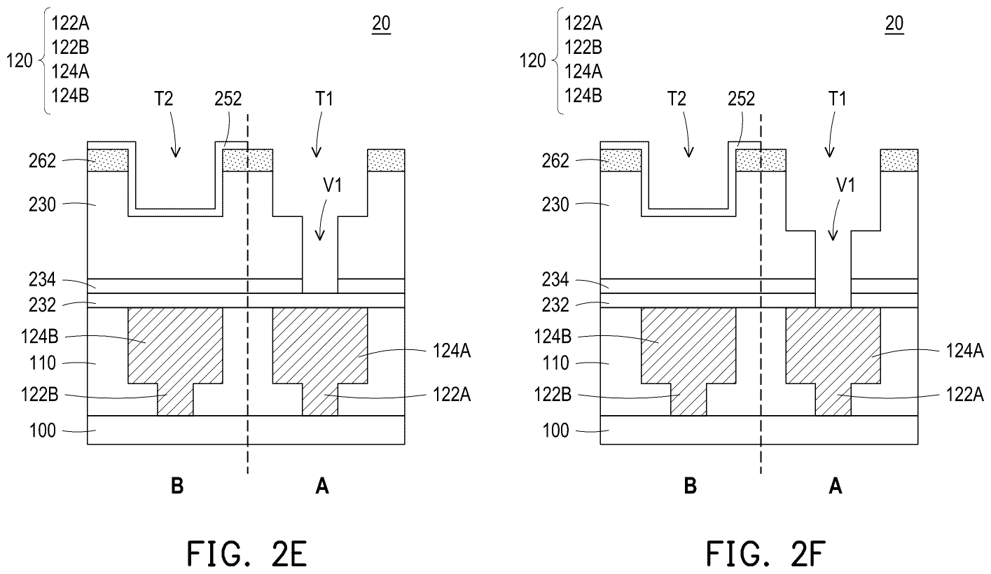

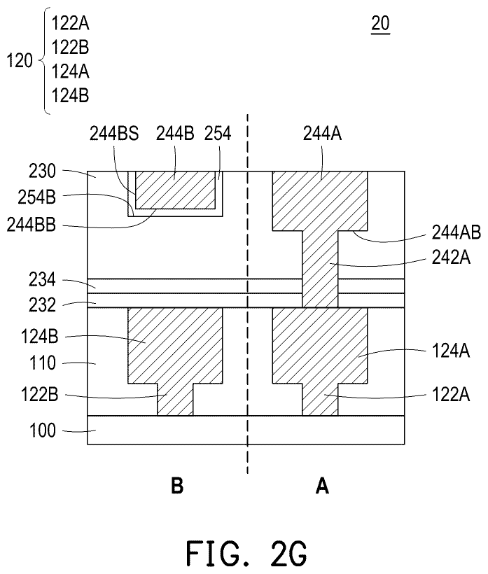

FIG. 2A to FIG. 2G are schematic cross-sectional views of a method of forming an interconnection structure according to a second embodiment of the disclosure. In the embodiment, the same or similar elements as those in the first embodiment will be indicated by the same or similar wording and reference numerals, and will not be described again.

The first embodiment of the disclosure (FIG. 1A to FIG. 1F) is a method of forming an interconnection structure in which trenches are formed first and then vias are formed. The second embodiment of the disclosure (FIG. 2A to FIG. 2G) is a method of forming an interconnection structure in which vias are formed first and then trenches are formed. Moreover, both the first and second embodiments of the disclosure use a hardmask to define the trenches, but the actual use is not limited thereto, and various photolithographic etching methods may be used to form the trenches and the vias.

First, refer to FIG. 2A and FIG. 2B. Similar to the structural stacking of FIG. 1A and FIG. 1B, the difference lies in that after patterning the hardmask layer (not shown) located on a second dielectric layer 230 to form a hardmask262, the second dielectric layer 230 in the lower voltage device region A is first patterned.

Referring to FIG. 2B, an elongated via VL is formed in the second dielectric layer 230 in the lower voltage device region A. For example, part of the second dielectric layer 230 in the lower voltage device region A is removed by using methods such as photolithographic etching to expose a first interlayer dielectric layer 232, as shown in FIG. 2B.

Then, as shown in FIG. 2C, the hardmask 262 is used together with methods such as etching to define the first via V1 in the lower voltage device region A, the first trench T1 located above the first via V1, and the second trench T2 in the higher voltage device region B.

In some embodiments, as shown in FIG. 2C, the second dielectric layer 230 around an upper half part of the elongated via VL is removed to expose a second interlayer dielectric layer 234, so as to form the first via V1 and the first trench T1 located above the first via V1. At the same time, part of the second dielectric layer 230 in the higher voltage device region B is removed to form the second trench T2.

Then, as shown in FIG. 2D, a high k layer 250 is conformally deposited on the first trench T1, the first via V1, the second trench T2, and the second dielectric layer 230. If the hardmask 262 is used to define the first trench T1 and the second trench T2 as in the embodiment, then as shown in FIG. 2D, the high k layer 250 is conformally deposited on the first trench T1, the first via V1, the second trench T2, and the hardmask 262.

Next, as shown in FIG. 2E, the high k layer 250 on the first trench T1 and the first via V1 in the lower voltage device region A is selectively removed to form a high k layer 252 that only exists on the second trench T2 in the higher voltage device region B.

Next, as shown in FIG. 2F, the second interlayer dielectric layer 234 at the bottom of the first via V1 is removed to expose the under-layer interconnection structure 120.

The step of exposing the under-layer interconnection structure 120 in the second embodiment (as shown in FIG. 2F), similar to the step of exposing the under-layer interconnection structure 120 in the first embodiment (as shown in FIG. 1E), is performed before the first via V1, the first trench T1, and the second trench T2 are filled with the conductive material, so as to prevent the exposed under-layer interconnection structure 120 from being oxidized or prevent the surface thereof from being damaged by other steps such as etching.

Then, the first via V1, the first trench T1, and the second trench T2 are filled with the conductive material, such as tantalum, titanium, copper, tungsten, aluminum, or some other suitable conductive materials, to electrically connected with the under-layer interconnection structure 120; for example, copper is filled into the first via V1, the first trench T1, and the second trench T2.

Then, a comprehensive planarization process is performed on an entire interconnection structure 20. For example, methods such as chemical mechanical polishing (CMP) are used to remove the excess conductive material, the high k layer 252, and the hardmask 262, so that the first via V1, the first trench T1, and the second trench T2 filled with the conductive material respectively form a first via plug 242A, a first metal layer 244A, and a second metal layer 244B, and the high k layer 252 is formed in the higher voltage device region B as a U-shaped high k layer 254 surrounding a bottom surface 244BB and sidewalls 244BS of the second metal layer 244B as shown in FIG. 2G.

As shown in FIG. 2G, a bottom surface 254B of the U-shaped high k layer 254 is higher than a bottom surface 244AB of the first metal layer 244A in a stacking direction.

A dielectric constant of the U-shaped high k layer 254 is higher than a dielectric constant of the second dielectric layer 230. For example, the U-shaped high k layer 254 has a dielectric constant of about 7 to 10, and the second dielectric layer 230 has a dielectric constant of about 3.1 to 3.9, but the disclosure is not limited to these values.

Moreover, the U-shaped high k layer 254 may include high k dielectric materials such as HfO₂, TiO₂, HfZrO, Ta₂O₃, HfSiO₄, ZrO₂, ZrSiO₂, LaO, AlO, ZrO, TiO, Ta₂O₅, Y₂O₃, BaZrO, HfLaO, HfSiO, LaSiO, AlSiO, HfTaO, HfTiO, Al₂O₃, SIN, SION, SiCN, or HfOx composite whose dielectric constant is greater than silicon oxide, with SIN, SiON, SiCN, or HfOx composite being preferred, and may be formed by methods such as atomic layer deposition (ALD) process or metal-organic chemical vapor deposition (MOCVD), but the disclosure is not limited thereto.

Like the first embodiment of the disclosure, since the U-shaped high k layer 254 located in the higher voltage device region B surrounds the bottom surface 244BB and sidewalls 244BS of the second metal layer 244B, it may make the overall dielectric layer in the higher voltage device region B have higher voltage withstand capability and improve the time dependent dielectric breakdown (TDDB) thereof. Therefore, it is no longer necessary to use the processing method in the conventional technology where the additional multi-layer interconnection structures such as metal layers/metal plugs/dielectric layers are added in the higher voltage device A to increase the thickness of the dielectric layer so as to withstand a higher voltage; that is to say, the disclosure forms the U-shaped high k layer 254 in the higher voltage device region B to surround the bottom surface 244BB and the sidewalls 244BS of the second metal layer 244B, so as to improve the time dependent dielectric breakdown (TDDB) thereof, and at the same time, reduce the need to form additional multi-layer interconnection structures such as metal layers/metal plugs/dielectric layers in order to withstand the voltage requirements of higher voltage devices, thereby reducing the manufacturing cost and the manufacturing time.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. An interconnection structure, comprising:
a substrate, comprising a lower voltage device region and a higher voltage device region;
a first dielectric layer, located on the substrate in the lower voltage device region and the higher voltage device region;
an under-layer interconnection structure, located in the first dielectric layer in the lower voltage device region and the higher voltage device region;
a second dielectric layer, located on the first dielectric layer in the lower voltage device region and the higher voltage device region;
a first via plug and a first metal layer, located in the second dielectric layer in the lower voltage device region; and
a U-shaped high k layer and a second metal layer, located in the second dielectric layer in the higher voltage device region,
wherein the U-shaped high k layer surrounds a bottom surface and sidewalls of the second metal layer, and
a bottom surface of the U-shaped high k layer and a bottom surface of the first metal layer are at a same level in a stacking direction.

2. The interconnection structure according to claim 1, wherein the substrate comprising the lower voltage device region and the higher voltage device region is the substrate comprising a low-voltage device and a medium-voltage device, the substrate comprising a low-voltage device and a high-voltage device, or the substrate comprising a medium-voltage device and a high-voltage device.

3. The interconnection structure according to claim 2, wherein a voltage operating range of the low-voltage device is 5V or less, a voltage operating range of the medium-voltage device is 6V to 10V, and a voltage operating range of the high-voltage device is 20V or more.

4. The interconnection structure according to claim 1, wherein a dielectric constant of the U-shaped high k layer is greater than a dielectric constant of the second metal layer.

5. The interconnection structure according to claim 1, wherein a dielectric constant of the U-shaped high k layer is 7 to 10, and the U-shaped high k layer comprises SIN, SiON, SiCN, or HfOx composite.

6. A method of forming an interconnection structure, comprising:
providing a substrate, comprising a lower voltage device region and a higher voltage device region;
forming a first dielectric layer on the substrate in the lower voltage device region and the higher voltage device region;
forming an under-layer interconnection structure in the first dielectric layer in the lower voltage device region and the higher voltage device region;
forming a second dielectric layer on the first dielectric layer in the lower voltage device region and the higher voltage device region;
forming a first trench and a second trench in the second dielectric layer, wherein the first trench is located in the lower voltage device region, and the second trench is in the higher voltage device region;
forming a U-shaped high k layer on a bottom surface and sidewalls of the second trench;
etching a bottom of the first trench to form a first via exposing the under-layer interconnection structure; and
filling the first via, the first trench, and the second trench with a conductive material to respectively form a first via plug, a first metal layer, and a second metal layer,
wherein a bottom surface of the U-shaped high k layer and a bottom surface of the first metal layer are at a same level in a stacking direction.

7. The method of forming the interconnection structure according to claim 6, wherein the substrate comprising the lower voltage device region and the higher voltage device region is the substrate comprising a low-voltage device and a medium-voltage device, the substrate comprising a low-voltage device and a high-voltage device, or the substrate comprising a medium-voltage device and a high-voltage device, a voltage operating range of the low-voltage device is 5V or less, a voltage operating range of the medium-voltage device is 6V to 10V, and a voltage operating range of the high-voltage device is 20V or more.

8. The method of forming the interconnection structure according to claim 6, wherein a dielectric constant of the U-shaped high k layer is greater than a dielectric constant of the second metal layer.

9. The method of forming the interconnection structure according to claim 6, wherein a dielectric constant of the U-shaped high k layer is 7 to 10, and the U-shaped high k layer comprises SiN, SiON, SiCN, or HfOx composite.

10. The method of forming the interconnection structure according to claim 6, wherein the step of forming the U-shaped high k layer on the bottom surface and the sidewalls of the second trench comprises:
conformally forming a high k layer on the first trench and the second trench;
removing the high k layer on the second trench;
after the conductive material is filled into the first via, the first trench, and the second trench, performing a comprehensive planarization step to remove the high k layer on the second dielectric layer so as to form the U-shaped high k layer.

11. An interconnection structure, comprising:
a substrate, comprising a lower voltage device region and a higher voltage device region;
a first dielectric layer, located on the substrate in the lower voltage device region and the higher voltage device region;
an under-layer interconnection structure, located in the first dielectric layer in the lower voltage device region and the higher voltage device region;
a second dielectric layer, located on the first dielectric layer in the lower voltage device region and the higher voltage device region;
a first via plug and a first metal layer, located in the second dielectric layer in the lower voltage device region; and
a U-shaped high k layer and a second metal layer, located in the second dielectric layer in the higher voltage device region,
wherein the U-shaped high k layer surrounds a bottom surface and sidewalls of the second metal layer, and
a bottom surface of the U-shaped high k layer is higher than a bottom surface of the first metal layer in a stacking direction.

12. The interconnection structure according to claim 11, wherein the substrate comprising the lower voltage device region and the higher voltage device region is the substrate comprising a low-voltage device and a medium-voltage device, the substrate comprising a low-voltage device and a high-voltage device, or the substrate comprising a medium-voltage device and a high-voltage device.

13. The interconnection structure according to claim 12, wherein a voltage operating range of the low-voltage device is 5V or less, a voltage operating range of the medium-voltage device is 6V to 10V, and a voltage operating range of the high-voltage device is 20V or more.

14. The interconnection structure according to claim 11, wherein a dielectric constant of the U-shaped high k layer is greater than a dielectric constant of the second metal layer.

15. The interconnection structure according to claim 11, wherein a dielectric constant of the U-shaped high k layer is 7 to 10, and the U-shaped high k layer comprises SiN, SiON, SiCN, or HfOx composite.

16. A method of forming an interconnection structure, comprising:
providing a substrate, comprising a lower voltage device region and a higher voltage device region;
forming a first dielectric layer on the substrate in the lower voltage device region and the higher voltage device region;
forming an under-layer interconnection structure in the first dielectric layer in the lower voltage device region and the higher voltage device region;
forming a second dielectric layer on the first dielectric layer in the lower voltage device region and the higher voltage device region;
forming an elongated via in the second dielectric layer in the lower voltage device region;
removing the second dielectric layer around an upper half part of the elongated via to form a first via and a first trench located above the first via;
forming a second trench in the second dielectric layer in the higher voltage device region;
forming a U-shaped high k layer on a bottom surface and sidewalls of the second trench; and
filling the first via, the first trench, and the second trench with a conductive material to respectively form a first via plug, a first metal layer, and a second metal layer,
wherein a bottom surface of the U-shaped high k layer is higher than a bottom surface of the second metal layer in a stacking direction.

17. The method of forming the interconnection structure according to claim 16, wherein the substrate comprising the lower voltage device region and the higher voltage device region is the substrate comprising a low-voltage device and a medium-voltage device, the substrate comprising a low-voltage device and a high-voltage device, or the substrate comprising a medium-voltage device and a high-voltage device, a voltage operating range of the low-voltage device is 5V or less, a voltage operating range of the medium-voltage device is 6V to 10V, and a voltage operating range of the high-voltage device is 20V or more.

18. The method of forming the interconnection structure according to claim 16, wherein a dielectric constant of the U-shaped high k layer is greater than a dielectric constant of the second metal layer.

19. The method of forming the interconnection structure according to claim 16, wherein a dielectric constant of the U-shaped high k layer is 7 to 10, and the U-shaped high k layer comprises 5 SiN, SiON, SiCN, or HfOx composite.

20. The method of forming the interconnection structure according to claim 16, wherein the step of forming the U-shaped high k layer on the bottom surface and the sidewalls of the second trench comprises:
conformally forming a high k layer on the first trench, the first via, and the second trench;
removing the high k layer on the second trench and the first via;
after the conductive material is filled into the first via, the first trench, and the second trench, performing a comprehensive planarization step to remove the high k layer on the second dielectric layer so as to form the U-shaped high k layer.
